(19) United States
(12) Patent Application Publication
(10) Pub. No.: US 2011/0277822 A1
(43) Pub. Date: Nov. 17, 2011

(54) COMPOSITE ELECTRON CONDUCTOR FOR USE IN PHOTOVOLTAIC DEVICES

(75) Inventors: Zhi Zheng, Shanghai (CN); Linan Zhao, Shanghai (CN); Marilyn Wang, Shanghai (CN); Anna Liu, Shanghai (CN)

(73) Assignee: HONEYWELL INTERNATIONAL INC., Morristown, NJ (US)

(21) Appl. No.: 12/777,749

(22) Filed: May 11, 2010

(51) Int. Cl. H01L 31/00; H01L 31/18

(52) U.S. Cl. 136/252; 438/57; 257/E31.003

(57) ABSTRACT

A photovoltaic device such as solar cell includes a substrate, a composite electron conductor layer adjacent to the substrate, an active layer coupled relative to the composite electron conductor layer, and an electrode electrically coupled to the active layer. In some embodiments, the composite electron conductor layer includes a mixture of different sized particles, such as a mixture of smaller nanoparticles along with larger ground up or otherwise processed nanopillar, nanowire, nanorod, nanotubes, inverse opal and/or any other suitable structured nanocomponents as desired. Methods for making such photovoltaic device are also disclosed.

### TECHNICAL FIELD

The disclosure relates generally to photovoltaic devices such as solar cells. More particularly, the disclosure relates to electron conducting materials for use in photovoltaic devices.

### BACKGROUND

A wide variety of photovoltaic devices have been developed for converting light into electricity. Of the known photovoltaic devices, each has certain advantages and disadvantages.

There is an ongoing need to provide alternative photovoltaic devices, as well as methods for manufacturing photovoltaic devices.

### SUMMARY

The disclosure relates generally to photovoltaic devices such as solar cells, and methods for manufacturing photovoltaic devices. An example photovoltaic device may be a solar cell that includes a substrate, a composite electron conductor layer adjacent to the substrate, an active layer coupled relative to the composite electron conductor layer, and an electrode electrically coupled to the active layer. In some instances, the composite electron conductor layer may include a mixture of different sized particles, such as a mixture of smaller nanoparticles along with larger ground up or otherwise processed nanopillar, nanowire, nanorod, nanotubes, inverse opal and/or any other suitable structured nanocomponents as desired.

Another example photovoltaic device may be a solar cell that includes a first electrode, with a composite electron conductor layer electrically coupled to the first electrode. The composite electron conductor layer may include a composite of smaller TiO₂ nanoparticles along with one or more larger structured nanoelements formed from processed TiO₂ nanopillars, TiO₂ nanowires, TiO₂ nanorods, TiO₂ nanotubes, TiO₂ inverse opals and/or any other suitable structured nanocomponents. An active layer may be provided above the composite electron conductor layer, and a hole conductor layer may be disposed on the active layer. A second electrode may be electrically coupled to the hole conductor layer.

An example method for manufacturing a photovoltaic device may include growing or otherwise providing an array of nanopillars, nanowires, nanorods, nanotubes, inverse opals and/or other structured nanocomponents on a substrate. A portion of the nanopillar, nanowire, nanorod, nanotubes, inverse opal or other structured nanocomponents may be removed from the substrate, and ground up or otherwise processed to form a number of structured nanoelements. Smaller nanoparticles may then be mixed with the larger structured nanoelements, along with one or more additives, to form a composite paste. The composite paste may be applied to a first electrode to define an electron conductor layer on the first electrode. An active layer may then be disposed on the electron conductor layer. A hole conductor layer may then be provided on the active layer.

The above summary is not intended to describe each disclosed embodiment or every implementation of the present invention. The Figures and Description which follow more particularly exemplify certain illustrative embodiments.

### BRIEF DESCRIPTION OF THE DRAWINGS

The invention may be more completely understood in consideration of the following description of various illustrative embodiments in connection with the accompanying drawing, in which:

FIG. 1 is a schematic perspective view of an illustrative solar cell partially in cross-section;

FIG. 2 is a schematic cross-sectional side view of a substrate having grown thereon a nanopillar, nanowire, nanorod, nanotubes, inverse opal and/or other structure;

FIG. 3 is a schematic view of a composite paste for use in manufacturing an illustrative solar cell;

FIG. 4 is a schematic perspective view of an electrode with a composite paste provided thereon;

FIG. 5 is a schematic view of a portion of an illustrative composite electron conductor; and

FIG. 6 is a schematic view of a portion of another illustrative composite electron conductor.

While the invention is amenable to various modifications and alternative forms, specifics thereof have been shown by way of example in the drawing and will be described in detail. It should be understood, however, that the intention is not to limit the invention to the particular embodiments described. On the contrary, the intention is to cover all modifications, equivalents, and alternatives falling within the spirit and scope of the invention.

### DESCRIPTION

For the following defined terms, these definitions shall be applied, unless a different definition is given in the claims or elsewhere in this specification.

All numeric values are herein assumed to be modified by the term “about,” whether or not explicitly indicated. The term “about” generally refers to a range of numbers that one of skill in the art would consider equivalent to the recited value (i.e., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The following description should be read with reference to the drawings. The drawings, which are not necessarily to scale, depict illustrative embodiments and are not intended to limit the scope of the invention.

A wide variety of photovoltaics and/or photovoltaic cells, such as solar cells, have been developed for converting sunlight into electricity. Some example solar cells include a layer of crystalline silicon. Second and third generation solar cells often use a thin film of photovoltaic material (e.g., a “thin” film) deposited or otherwise provided on a substrate. These solar cells may be categorized according to the type of photovoltaic material deposited. For example, inorganic thin-film photovoltaics may include a thin film of amorphous silicon, microcrystalline silicon, CdS, CdTe, Cu₂S, copper indium diselenide (CIS), copper indium gallium diselenide (CIGS), etc. Organic thin-film photovoltaics may include a thin film of a polymer or polymers, bulk heterojunctions, ordered heterojunctions, a fullerence, a polymer/fullerence blend, photosynthetic materials, etc. These are only examples.

Solar cells typically include an electron conductor or a layer of electron conducting material (e.g., an electron conducting layer). Some electron conductors or electron conductor layers may include a plurality of electron conductor “nanoparticles”. For the purposes of this disclosure, an electron conductor nanoparticle is understood to be an electron conducting particle that has a size on the order of tens of nanometers (i.e. average maximum outer dimension of less than 100 nanometers). Nanoparticles may be desirable for an electron conductor layer for a number of reasons. Because of their relatively small size, nanoparticles may provide a relative large surface area so that a relatively large (e.g., by area) active layer (e.g., a photoactive layer) may be loaded onto the electron conductor layer that is made up of the nanoparticles. However, because there may be a number of boundaries between the nanoparticles, electron transport may be hindered. Thus, while nanoparticles may have a desirable surface area for loading a photoactive layer thereon, the conductivity of layers that include nanoparticles may be lower than desired.

Other electron conductors or electron conductor layers may include a plurality of structured nanocomponents such as an array of nanopillars, nanowires, nanorods, nanotubes, inverse opal or the like. In many cases, the structured nanocomponents may have a size on the order of hundreds of nanometers (i.e. average maximum outer dimension of greater than or equal to 100 nanometers). Such structured nanocomponents may be desirable for use in an electron conductor layer for a number of reasons. For example, structured nanocomponents, for example due to their relatively larger size as compared to nanoparticles, may have a relatively larger amount of crystallinity and fewer boundaries such that they can provide more desirable conductivity. However, structured nanocomponents may have less surface area available for loading a photoactive layer thereon. Thus, while structured nanocomponents may have a more desirable conductivity, the surface area for loading a photoactive layer thereon may be relatively low. The nanoparticles

The solar cells described herein may be fabricated in a way that combines the desirable properties of both the nanoparticles and the structured nanocomponents in a composite electron conductor layer. In some instances, the composite electron conductor layer may include a mixture of different sized particles, such as a mixture of the smaller nanoparticles along with the larger ground up or otherwise processed nanopillar, nanowire, nanorod, nanotubes, inverse opal and/or any other suitable structured nanocomponents as desired. This may result in an electron conductor layer that provides both a relatively large surface area and a relatively high conductivity. Some additional details regarding such composite electron conductor layers as well as additional features of the solar cells disclosed herein can be found below.

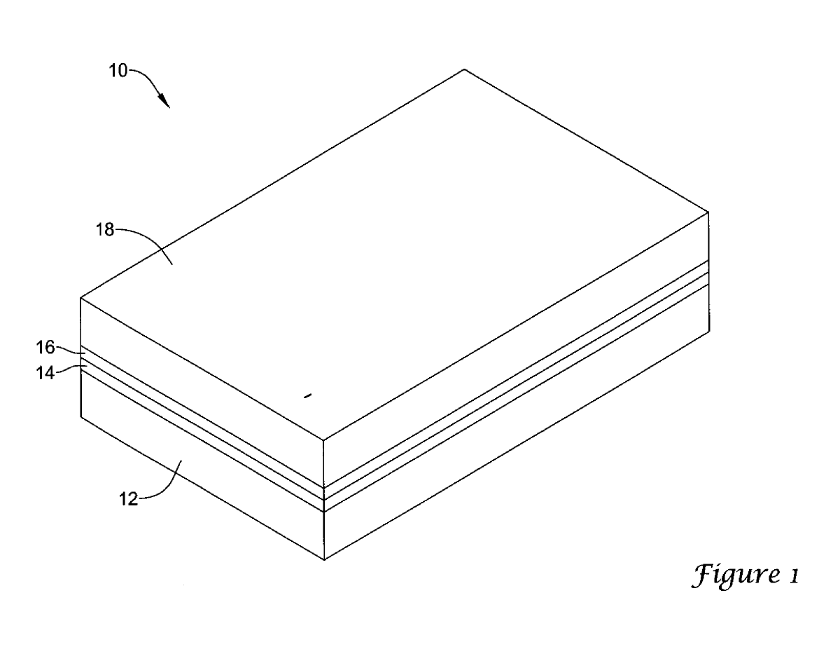

FIG. 1 is a schematic perspective view of an illustrative solar cell partially in cross-section 10. In the illustrative embodiment, solar cell 10 includes a substrate or first electrode (e.g., an anode or negative electrode) 12. An electron conductor layer 14 is shown electrically coupled to or otherwise disposed on electrode 12. An active layer 16 is electrically coupled to or otherwise disposed on electron conductor layer 14. Finally, a hole conductor 18 is shown electrically coupled to or otherwise disposed on active layer 16. Although not shown, solar cell 10 may also include a second electrode 20 (e.g., an cathode or positive electrode) that is electrically coupled to hole conductor layer 18.

Substrate/electrode 12 may be made from any number of different materials including polymers, glass, and/or transparent materials. In one example, substrate 12 may include polyethylene terephthalate, polyimide, low-iron glass, fluorine-doped tin oxide, indium tin oxide, Al-doped zinc oxide, any other suitable conductive inorganic element(s) or compound(s), conductive polymer(s), and other electrically conductive materials, combinations thereof, or any other suitable material or materials as desired.

Electron conductor layer 14 may be formed of any suitable material or material combination. In some cases, electron conductor layer 14 may be an n-type electron conductor. The electron conductor layer 14 may be metallic, such as TiO₂, ZnO, SnO₂, or the like. In some cases, electron conductor layer 14 may be an electrically conducting polymer, such as a polymer that has been doped to be electrically conducting or to improve its electrical conductivity.

In one illustrative embodiment, active layer 16 may include a photosensitive dye 20 that may be disposed, for example, adjacent layer 14. Photosensitive dye 20 may be any suitable material. For example, photosensitive dye 20 may include triscarboxy-ruthenium terpyridine [Ru(4,4′,4″-(COOH)₃-terpy)(NCS)₃], a ruthenium-polypyridine dye, other ruthenium complex materials, 1-ethyl-3 methylimidazolium tetrocyanoborate [EMIB(CN)₄], copper-diselenium [Cu(In,GA)Se₂], and the like, or any other suitable materials. In general, the photosensitive dye may be configured to release or otherwise inject electrons upon absorption of a photon. In other embodiments, one or more alternative or additional semiconductor materials may be utilized in cell 10 in order to generate electrons and/or holes.

In another illustrative embodiment, active layer 16 may include one or more polymers or polymer layers. In one example, active layer 16 may include an interpenetrating network of electron donor and electron acceptor polymers. In at least some embodiments, active layer 20 may include an interpenetrating network of poly-3-hexylthiophen (P3HT) and [6,6]-phenyl-C61-butyric acid methyl ester (PCBM). It is contemplated that other materials may be used, as desired. P3HT is a photoactive polymer. Consequently, the P3HT material may absorb light and generate electron-hole pairs (excitons).

In still another illustrative embodiment, active layer 16 may include a quantum dot layer. For example, the quantum dot layer may include one quantum dot or a plurality of quantum dots. Quantum dots are typically very small semiconductors, having dimensions in the nanometer range. Because of their small size, quantum dots may exhibit quantum behavior that is distinct from what would otherwise be expected from a larger sample of the material. In some cases, quantum dots may be considered as being crystals composed of materials from Groups II-VI, III-V, or IV-VI materials. The quantum dots employed herein may be formed using any appropriate technique. Examples of specific pairs of materials for forming quantum dots include, but are not limited to, MgO, MgS, MgSe, MgTe, CaO, CaS, CaSe, CaTe, SrO, SrS, SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S₃, Al₂Se₃, Al₂Te₃, Ga₂O₃, Ga₂S₃, Ga₂Se₃, Ga₂Te₃, In₂O₃, In₂S₃, In₂Se₃, In₂Te₃, SiO₂, GeO₂, SnO₂, SnS, SnSe, SnTe, PbO, PbO₂, PbS, PbSe, PbTe, AlN, AlP, AlAs, AlSb, GaN, GaP, GaAs, GaSb, InN, InP, InAs and InSb.

In some embodiments, solar cell 10 may include a bifunctional ligand layer (not shown) that may help to couple active layer 16 (e.g., where active layer 16 is a quantum dot layer) with electron conductor layer 14. At least some of the bifunctional ligands within the bifunctional ligand layer may be considered as including electron conductor anchors that may bond to electron conductor layer 14, and quantum dot anchors that may bond to individual quantum dots within active layer 16. A wide variety of bifunctional ligand layers are contemplated for use with the solar cells disclosed herein.

Hole conductor layer 18 may be considered as being coupled to active layer 16. In some cases, two layers may be considered as being coupled if one or more molecules or other moieties within one layer are bonded or otherwise secured to one or more molecules within another layer. In some instances, coupling infers the potential passage of electrons from one layer to the next.

Hole conductor layer 18 may be formed of any suitable material or material combination. For example, hole conductor layer 18 may be a p-type electron conductor. In some cases, hole conductor layer 18 may include a conductive polymer, but this is not required. In some cases, the conductive polymer may include a monomer that has an alkyl chain that terminates in a second quantum dot anchor. The conductive polymer may, for example, be or otherwise include a polythiophene that is functionalized with a moiety that bonds to quantum dots. In some cases, the polythiophene may be functionalized with a thio or thioether moiety.

An illustrative but non-limiting example of a suitable conductive polymer has

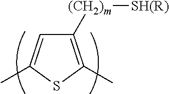

as a repeating unit, where R is absent or alkyl and m is an integer ranging from about 6 to about 12.

Another illustrative but non-limiting example of a suitable conductive polymer has

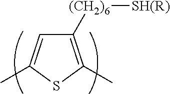

as a repeating unit, where R is absent or alkyl.

Another illustrative but non-limiting example of a suitable conductive polymer has

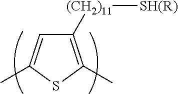

as a repeating unit, where R is absent or alkyl.

Another illustrative but non-limiting example of a suitable conductive polymer has

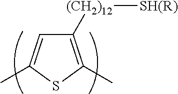

as a repeating unit, where R is absent or alkyl.

As indicated above, in at least some embodiments, electron conductor layer 14 may be a “composite” electron conductor layer 14 that includes a mixture of different sized particles, such as a mixture of smaller nanoparticles along with larger ground up or otherwise processed nanopillar, nanowire, nanorod, nanotubes, inverse opal and/or any other suitable structured nanocomponents as desired. This may result in an electron conductor layer that provides both a relatively large surface area and a relatively high conductivity.

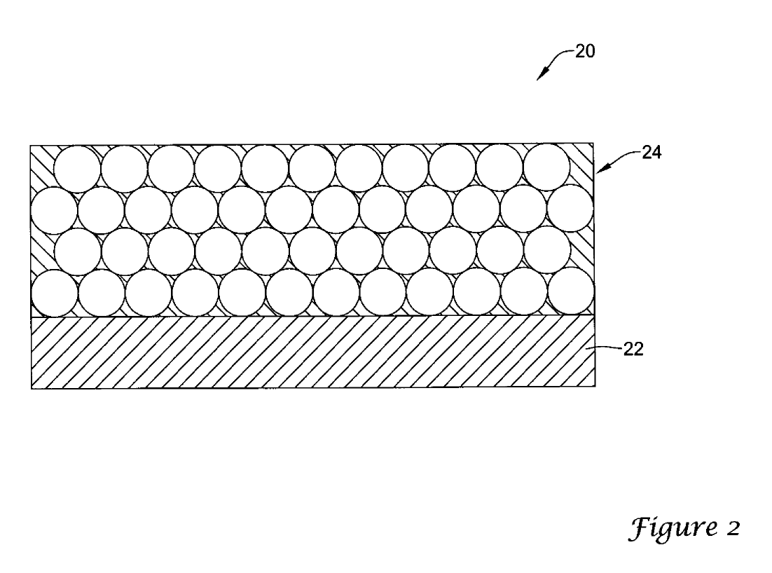

Forming such a composite electron conductor layer 14 may include a number of steps. For example, as illustrated in FIG. 2, a microstructured array 24 of nanopillars, nanowires, nanorods, nanotubes, inverse opals and/or other structured nanocomponents may be grown or otherwise formed on a substrate 22. In some instances, the microstructured array 24 may be made from electron conducting material such as TiO₂, ZnO, SnO₂, or the like. In some cases, microstructured array 24 may have a suitable three-dimensional structural arrangement. For example, microstructured array 24 may include an inverse opal film as shown in FIG. 2. Alternatively, microstructured array 24 may include any number of structured nanocomponents such as nanopillar, nanowire, nanorod, nanotubes, inverse opals, arranged in any suitable manner.

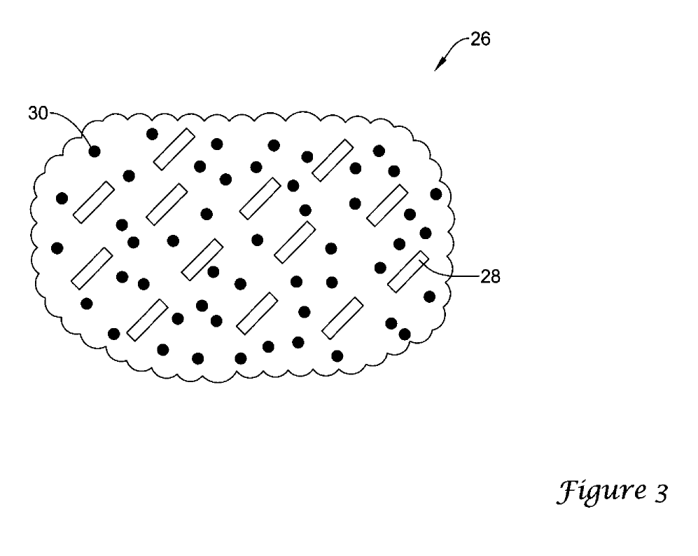

Next, and in some instances, a portion of the microstructured array 24 may be removed from assembly 20. This may include scratching, etching, or using any other suitable technique for removing a desired portion of microstructured array 24 from assembly 20. In some cases, the removed material may be ground or otherwise processed into smaller pieces, referred to herein as nanoelements. In some cases, such nanoelements may have an average maximum outer dimension of greater than or equal to 100 nanometers and less than 1 micrometer. A composite paste 26 may be formed by mixing these nanoelements with smaller nanoparticles, sometimes with one or more additives as illustrated in FIG. 3. The smaller nanoparticles are shown at 30, and the larger nanoelements are shown at 28. The one or more additives may include one or more of polyethylene glycol, a surfactant, terpineol, or any other suitable additive as desired. The structured nanocomponents, and thus the larger nanoelements, may have a different shape than the nanoparticles.

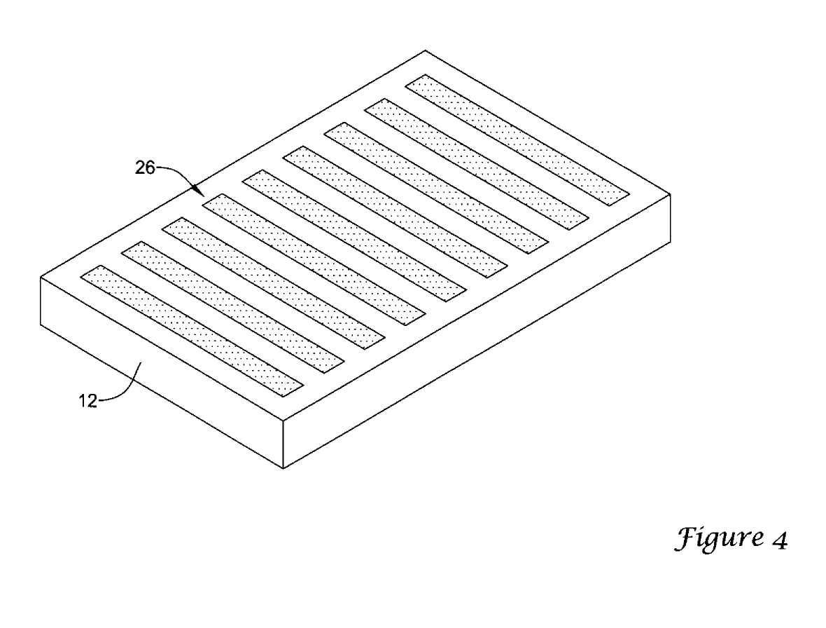

Composite paste 26 may, in some cases, be applied onto an electrode/substrate 12. In some instances, composite paste 26 may be arranged in a pattern such as in a plurality of rows as shown in FIG. 4. Alternatively, paste 26 may be disposed on a substrate 12 so as to cover essentially the entire top surface thereof, or in any other suitable arrangement as desired. In some cases, composite paste 26 may be applied to electrode/substrate 12 by, for example, screen printing, using a doctor blade, or the like. If desired, composite paste 26 may be sintered at a high temperature once applied. This may form composite electron conductor layer 14. The remaining structure of solar cell 10 may then be added to the electron conductor layer 14. For example, active layer 16 may be provided on composite electron conductor layer 14, followed by a hole conductor 18, and then a second electrode 20 as desired. Other structures may also be added such as, for example, suitable packaging material.

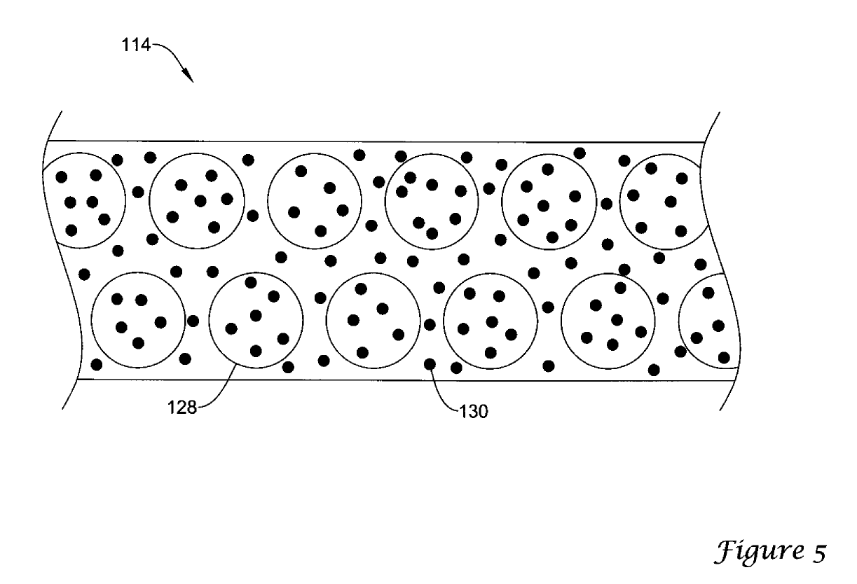

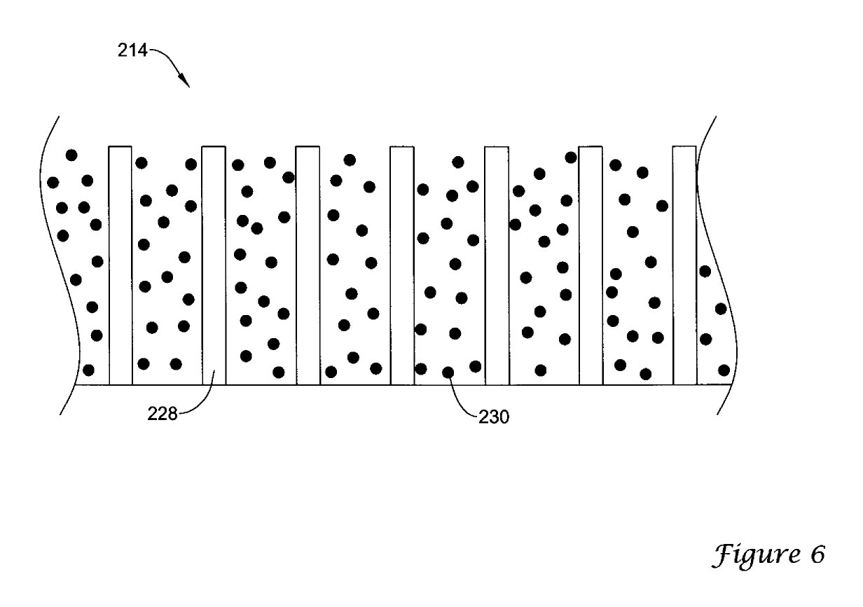

FIGS. 5-6 illustrate some similar arrangements contemplated for composite electron conductor layer 14. While these figures use new reference numbers, it is contemplated that these illustrated composite electron conductor layers may be used in conjunction with solar cell 10, or variations of solar cell 10 as desired. FIG. 5 is a schematic view of a portion of an illustrative composite electron conductor, where the structured nanocomponents take the form of an inverse opal film 128. A plurality of nanoparticles 130 are shown dispersed throughout the inverse opal film 128. Here, the composite electron conductor layer 114 may be formed by adding a plurality of nanoparticles 130 to or on the inverse opal film 128. This may include the steps as described above or it may include other steps such as directly adding nanoparticles 130 to the inverse opal film 128. In this illustrative embodiment, the inverse opal film 128 may or may not be ground or otherwise processed into structured nanoelements before adding the nanoparticles 130.

FIG. 6 is a schematic view of a portion of another illustrative composite electron conductor, where the structured nanocomponents take the form of nanowires 228. A plurality of nanoparticles 230 are shown dispersed throughout an array of nanowires 228. Here, the composite electron conductor layer 214 may be formed by adding the plurality of nanoparticles 230 to the nanowires 228. This may include the steps as described above or it may include other steps such as directly adding nanoparticles 230 to the nanowires 228. In this illustrative embodiment, the nanowires 228 may or may not be ground or otherwise processed into structured nanoelements before adding the nanoparticles 230, as desired. Numerous other arrangements are also contemplated.

It should be understood that this disclosure is, in many respects, only illustrative. Changes may be made in details, particularly in matters of shape, size, and arrangement of steps without exceeding the scope of the invention. The invention's scope, of course, is defined in the language in which the appended claims are expressed.

What is claimed is:

1. A solar cell, comprising:
a first electrode;
a composite electron conductor layer electrically coupled to the first electrode, the composite electron conductor layer including a mixture of different sized particles;
an active layer coupled to the composite electron conductor layer; and
a second electrode electrically coupled to the active layer.

2. The solar cell of claim 1, wherein the mixture of different sized particles includes a plurality of smaller nanoparticles and a plurality of larger structured nanoelements.

3. The solar cell of claim 2, wherein the plurality of larger structured nanoelements include ground up portions of one or more of nanopillar, nanowire, nanorod, nanotubes and inverse opals.

4. The solar cell of claim 1, wherein the mixture of different sized particles includes a plurality of smaller nanoparticles and a plurality of structured nanocomponents.

5. The solar cell of claim 4, wherein the plurality of larger structured nanocomponents include one or more nanopillar, nanowire, nanorod, nanotubes and inverse opals.

6. The solar cell of claim 1, wherein the mixture of different sized particles includes particles of different shapes.

7. The solar cell of claim 1, wherein the composite electron conductor layer includes one or more of TiO₂, ZnO, and SnO₂.

8. The solar cell of claim 1, wherein the active layer includes a photosensitive dye.

9. The solar cell of claim 1, wherein the active layer includes one or more quantum dots.

10. The solar cell of claim 1, further comprising a hole conductor layer disposed between the active layer and the second electrode.

11. A solar cell, comprising:
a first electrode;
an electron conductor layer coupled to the first electrode, the electron conductor layer being a composite of TiO₂ nanoparticles and structured TiO₂ nanoelements;
an active layer situated adjacent to the electron conductor layer;
a hole conductor layer disposed adjacent to the active layer; and
a second electrode electrically coupled to the hole conductor layer.

12. The solar cell of claim 11, wherein the first electrode is an anode and the second electrode is a cathode.

13. The solar cell of claim 11, wherein the structured TiO₂ nanoelements include ground up portions of one or more of TiO₂ nanowires, TiO₂ nanorods, TiO₂ nanotubes, and TiO₂ inverse opals.

14. The solar cell of claim 11, wherein the active layer includes a photosensitive dye.

15. The solar cell of claim 11, wherein the active layer includes one or more quantum dots.

16. A method for manufacturing a solar cell, the method comprising:
providing a substrate;
growing a microstructured array on the substrate, the microstructured array including a plurality of structured nanocomponents;
removing a portion of the structured nanocomponents from the substrate;
processing the removed structured nanocomponents to form nanoelements;
forming a composite paste by mixing a plurality of nanoparticles with the nanoelements, wherein the plurality of nanoparticles are smaller than the nanoelements;
applying the composite paste to a first electrode, wherein the composite paste defines an electron conductor layer; and
disposing an active layer on the composite electron conductor layer.

17. The method of claim 16, wherein the composite paste further includes an additive, wherein the additive is one or more of polyethelyne glycol, a surfactant, and terpineol.

18. The method of claim 16, wherein the composite paste is applied to the first electrode by screen printing.

19. The method of claim 16, further comprising sintering the electron conductor layer.

20. The method of claim 16, further comprising providing a hole conductor layer adjacent to the active layer, and providing a second electrode adjacent to the hole conductor layer.
